(19) United States
(12) Patent Application Publication
(10) Pub. No.: US 2009/0206433 A1
(43) Pub. Date: Aug. 20, 2009

(54) Image sensor and method for manufacturing the same

(76) Inventor: Sung-Hyun Kang, Mapo-gu (KR)

Correspondence Address: SHERR & VAUGHN, PLLC, 620 HERNDON PARKWAY, SUITE 200, HERNDON, VA, 20170, US

(21) Appl. No.: 12/344,405

(22) Filed: Dec. 26, 2008

(30) Foreign Application Priority Data
Dec. 26, 2007 (KR) 10-2007-0137272

(51) Int. Cl. H01L 31/0232; G02B 11/02; B05D 5/12; H01L 31/18

(52) U.S. Cl. 257/432; 359/796; 427/58; 216/39; 257/E31.127

(57) ABSTRACT

An image sensor and a method for manufacturing the same that includes a dielectric layer having a trench formed therein, a first micro-lens having a first structure formed in the trench, and a second micro-lens having a second structure formed over and contacting the first micro-lens such that the second structure is different than the first structure.

The present application claims priority under 35 U.S.C. § 119 of Korean Patent Application No. 10-2007-0137272, filed Dec. 26, 2007, which is hereby incorporated by reference in its entirety.

### BACKGROUND

A micro-photo process is performed using a special photoresist for a micro-lens, and then a reflowing scheme is performed to form the micro-lens in q manufacturing process for forming of image sensor. Vignetting occurs in such an image sensor of the related art. Vignetting refers to a phenomenon in which illumination falls off in the edges or the contour of a photographed image due to the reduction of an amount of light at the peripheral portion of the micro-lens. A small amount of vignetting occurs in a single-lens reflex (SLR) camera. Even if the vignetting occurs in the SLR camera, a lens is replaced with another lens, so that the vignetting can be prevented. However, as an image sensor is applied to small-size image appliances such as a miniature digital camera, a mobile phone, and a surveillance camera, the vignetting cannot be overcome by improving only the structure of the lens.

As technology for image sensors have developed, the image sensor has been employed for various appliances. In particular, as the demand of the image sensor becomes increased in small-size home electronics and small-size video appliances, the use range of the image sensor becomes expanded. Accordingly, a small-size image sensor having a high quality has been increasingly required. As the image sensor becomes downsized, vignetting, which does not cause a problem or can be overcome through the improvement of a lens structure in middle-size or large-size video appliances, must be overcome by improving the internal structure of an image sensor chip.

### SUMMARY

Accordingly, the embodiment provides an image sensor and a method for manufacturing the same, capable of overcoming vignetting.

An image sensor according to the embodiment includes a photodiode on a substrate, an interlayer dielectric layer on the photodiode, in which the interlayer dielectric layer is formed at a lower portion thereof with a trench, a first micro-lens filled in the trench, and a second micro-lens on the first micro-lens.

Embodiments relate to a method for manufacturing an image sensor that may include at least one of the following: forming a photodiode on and/or over a substrate, forming an interlayer dielectric layer on and/or over the photodiode, forming a first micro-lens having a concave structure on and/or over the interlayer dielectric layer, and forming a second micro-lens having a convex structure on and/or over the first micro-lens.

Embodiments relate to a method that may include at least one of the following: forming a photodiode on and/or over a substrate, forming an interlayer dielectric layer on and/or over the photodiode, forming a first micro-lens having a first geometric structure on and/or over the interlayer dielectric layer, and forming a second micro-lens having a second geometric structure on and/or over the first micro-lens such that the second geometric structure is different than the first geometric structure.

Embodiments relate to a device that may include at least one of the following: a photodiode formed on and/or over a substrate, an interlayer dielectric layer formed on and/or over the photodiode, a first micro-lens having a first geometric structure formed on and/or over the interlayer dielectric layer, and a second micro-lens having a second geometric structure formed on and/or over the first micro-lens such that the second geometric structure is different than the first geometric structure.

Embodiments relate to a device that may include at least one of the following: a photodiode formed at a substrate; a dielectric layer formed over the photodiode; a trench formed in the dielectric layer; a first micro-lens formed in the trench; and a second micro-lens formed over the first micro-lens.

Embodiments relate to a device that may include at least one of the following: a layer having a trench formed therein; a lower micro-lens having a first structure formed in the trench; and an upper micro-lens having a second structure formed over and contacting the lower micro-lens, wherein the second structure is different than the first structure.

Embodiments relate to a method that may include at least one of the following: providing a dielectric layer; and then forming a first micro-lens having a first structure in the dielectric layer; and then forming a second micro-lens having a second structure over and contacting the first micro-lens, wherein the second structure is different than the first structure.

### DRAWINGS

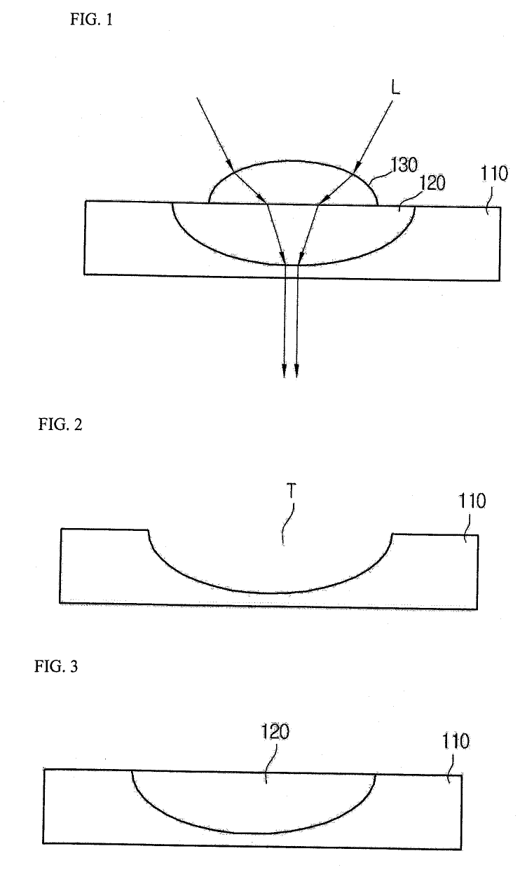

Example FIGS. 1 to 4 illustrate an image sensor and a method for manufacturing an image sensor in accordance with embodiments.

### DESCRIPTION

Example FIG. 1 is a sectional view showing an image sensor in accordance with embodiments that may include a photodiode provided on and/or over or in a substrate, interlayer dielectric layer 110 formed on and/or over the photodiode. Trench T formed in the interlayer dielectric layer 110 having a concave geometric cross-section. First micro-lens 120 is formed in trench T and second micro-lens 130 is formed on and/or over first micro-lens 120. In accordance with embodiments, second micro-lens 130 includes a material having a refractive index lower than that of first micro-lens 120, thereby changing the path of light L obliquely incident on second micro-lens 130 such that light L is incident on the photodiode. For example, first micro-lens 120 includes a material having a refractive index in a range between approximately 1.4 to 1.6. First micro-lens 120 may be composed of a material such as titanium oxide (TiO₂), but is not limited thereto. First micro-lens 120 may be formed by using a photoresist (PR) film having a refractive index of about 1.

In accordance with embodiments, vignetting can be overcome by using the curvature of a micro-lens in addition to the refractive index of the micro-lens. For example, as shown in example FIG. 1, first micro-lens 120 has a concave cross-section while second micro-lens 130 has a convex cross-section so that the path of the light L can be induced on and/or over the photodiode. In accordance with embodiments, the path of light L may be induced on and/or over the photodiode using a difference in curvatures between first micro lens 120 and second micro-lens 130. In other words, since first micro-lens 120 has a size greater than that of second micro-lens 130, first micro-lens 120 must have a curvature less than a curvature of second micro-lens 130 to easily collect the light L on and/or over the photodiode.

In the image sensor in accordance with embodiments, the ability of a micro-lens is maximized through the adjustment of the refractive index and the curvature of the micro-lens at the chip level, such that vignetting is overcome. Meaning, the structure of the micro-lens in a chip edge area, where vignetting occurs, is modified so that the path of the light is changed through the micro-lens. In other words, the structure of the micro-lens is maximized, such that the light is refracted at both interfacial surfaces of the upper micro-lens 130 and the lower micro-lens 120, thereby allowing light to be incident onto the photodiode.

Hereinafter, the method for manufacturing the image sensor in accordance with embodiments will be described with reference to example FIGS. 2 to 4. A photodiode is formed on and/or over or in a substrate. The photodiode may be formed by implanting ions in the substrate or by depositing a crystalline layer on and/or over an amorphous layer. Thereafter, as shown in example FIG. 2, interlayer dielectric layer 110 is formed on and/or over the photodiode. A color filter layer and a planarization layer may be further formed before interlayer dielectric layer 110 is formed. Then, trench T having a concave cross-section is formed in interlayer dielectric layer 110. Trench T may be formed through an isotropic wet etch process.

Subsequently, as shown in example FIG. 3, first micro-lens 120 is formed in interlayer dielectric layer 110. For example, first micro-lens 120 may be formed by filling trench T with a material having a refractive index in a range between approximately 1.4 to 1.6. Although first micro-lens 120 may be composed of TiO₂, it is not limited thereto. First micro-lens 120 is filled in trench T, and then a CMP process may be further performed with respect to the resultant structure.

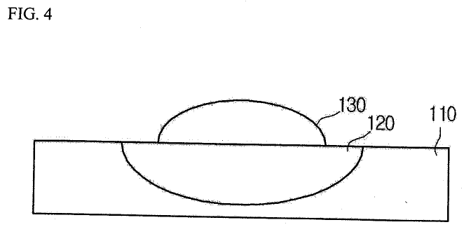

Next, as shown in example FIG. 4, second micro-lens 130 is formed on and/or over first micro-lens 120. Second micro-lens 130 includes a material having a refractive index less than that of first micro-lens 120. For example, although first micro-lens 120 may be formed through an exposure and reflow process using a photoresist (PR) film having a refractive index of about 1, embodiments are not limited thereto. In accordance with embodiments, second micro-lens 130 may have a convex cross-section. Accordingly, the image sensor in accordance with embodiments includes a multi-structure micro-lens structure including upper and lower micro-lenses 130 and 120.

In accordance with embodiments, the curvature of the micro-lens and the refractive index of a material for the micro-lens in the dual micro-lens structure are important factors to overcome vignetting. For example, although upper micro-lens 130 includes a photoresist (PR) film having a refractive index of about 1 and lower micro-lens 120 includes TiO₂ having a refractive index in a range between approximately 1.4 to 1.6, embodiments are not limited thereto. Using materials having different refractive indices for the two micro-lenses is necessary to refract a traveling path of light based on the difference between the refractive indices such that the light can be incident onto the photodiode provided under the micro-lens.

In accordance with embodiments, the curvatures of the micro-lenses are an important factor together with the refractive indices. Light is primarily refracted at the interfacial surface between the air and the upper micro-lens, secondarily refracted at the interfacial surface between the upper micro-lens and the lower micro-lens, and tertiary refracted at the interfacial surface between the lower micro-lens and a chip, so that the light can be incident onto the photodiode provided under the micro-lens. Moreover, light can be induced on and/or over the photodiode due to the difference in curvatures between the micro-lenses. For example, since lower micro-lens 120 has a size greater than the size of upper micro-lens 130, lower micro-lens 120 may have a curvature smaller than that of the upper micro-lens 130 to easily collect light on and/or over the photodiode.

Accordingly, as shown in example FIG. 4, if the micro-lens is prepared by using two lenses having different curvatures and being bonded to each other, light can be easily incident onto the photodiode. In order to overcome the vignetting, the maximization of the optic lens is required at the chip level.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a photodiode formed at a substrate;
a dielectric layer formed over the photodiode;
a trench formed in the dielectric layer;
a first micro-lens formed in the trench; and
a second micro-lens formed over the first micro-lens.

2. The device of claim 1, wherein the second micro-lens has a convex cross-section and the first micro-lens has a concave cross-section.

3. The device of claim 1, wherein the first micro-lens is composed of a material having a first refractive index and the second micro-lens is composed of a material having a second refractive index lower than the first refractive index.

4. The device of claim 1, wherein the second micro-lens is composed of a photoresist film.

5. The device of claim 4, wherein the first micro-lens is composed of an oxide material.

6. The device of claim 5, wherein the oxide material comprises titanium oxide (TiO₂).

7. The device of claim 1, wherein the second micro-lens has a radius of curvature greater than a radius of curvature of the first micro-lens.

8. A device comprising:
a dielectric layer having a trench formed therein;
a lower micro-lens having a first structure formed in the trench; and
an upper micro-lens having a second structure formed over and contacting the lower micro-lens, wherein the second structure is different than the first structure.

9. The device of claim 8, wherein the first structure comprises a concave structure.

10. The device of claim 8, wherein the second structure comprises a convex structure.

11. The device of claim 8, wherein the lower micro-lens is composed of a first material and the upper micro-lens is composed of a second material different than the first material.

12. The device of claim 8, wherein the lower micro-lens is composed of a first material having a first refractive index and the upper micro-lens is composed of a second material having a second refractive index lower than the first refractive index.

13. The device of claim 13, wherein the first refractive index is in a range between approximately 1.4 to 1.6.

14. The device of claim 13, wherein the second refractive index is about 1.

15. The device of claim 8, wherein the lower micro-lens has a first radius of curvature and the upper micro-lens has a second radius of curvature greater than the first radius of curvature.

16. The device of claim 8, wherein the upper micro-lens is composed of a photoresist film and the lower micro-lens is composed of an oxide material.

17. A method comprising:
providing a dielectric layer; and then
forming a first micro-lens having a first structure in the dielectric layer; and then
forming a second micro-lens having a second structure over and contacting the first micro-lens, wherein the second structure is different than the first structure.

18. The method of claim 17, wherein forming the first micro-lens comprises:
forming a trench having the first structure in the dielectric layer; and then
filling the trench with an oxide material.

19. The method of claim 17, wherein the first structure comprises a concave structure and the second structure comprises a convex structure.

20. The method of claim 17, wherein the first micro-lens has a first radius of curvature and the second micro-lens has a second radius of curvature greater than the first radius of curvature.
